(19) United States
(12) Patent Application Publication
(10) Pub. No.: US 2026/0329321 A1
(43) Pub. Date: Oct. 22, 2026

(54) VOLTAGE REGULATOR AND OPERATION METHOD THEREOF

(71) Applicant: Samsung Electronics Co., Ltd., Suwon-si (KR)

(72) Inventors: Seunggyu LEE, Suwon-si (KR); Seongmun PARK, Suwon-si (KR); Youngjin MOON, Suwon-si (KR); Hanbyul KIM, Suwon-si (KR); Yong-Seong ROH, Suwon-si (KR)

(73) Assignee: Samsung Electronics Co., Ltd., Suwon-si (KR)

(21) Appl. No.: 19/413,420

(22) Filed: Dec. 9, 2025

(30) Foreign Application Priority Data
Apr. 16, 2025 (KR) 10-2025-0049629

(51) Int. Cl. G05F 1/575; G05F 1/571; H03F 1/02; H03F 3/45

(52) U.S. Cl. CPC G05F 1/575; G05F 1/571; H03F 1/0233; H03F 3/45273; H03F 2200/471; H03F 2200/78

(57) ABSTRACT

A voltage regulator may include an error amplifier including a first input terminal receiving a reference voltage, a second input terminal connected to a feedback node, and a first output terminal configured to output a pass gate voltage, and a pass transistor connected between an input voltage and an output node. The pass transistor is configured to operate in response to the pass gate voltage. The voltage regulator also includes a first resistor connected between the output node and the feedback node, a second resistor connected between the feedback node and a ground voltage, and a recovery enhancement circuit configured to provide one or more driving currents to the error amplifier and configured to control a magnitude of the one or more driving currents based on an output voltage of the output node.

### CROSS-REFERENCE TO RELATED APPLICATION

This U.S. non provisional application claims priority under 35 U.S.C. § 119 to Korean Patent Application No. 10-2025-0049629 filed with the Korean Patent Office on Apr. 16, 2025, the entire contents of which are incorporated herein by reference.

### BACKGROUND

Some example embodiments of the present disclosure relate to a voltage regulator and an operation method thereof.

Different types of voltage regulators are used to provide power to a load with specific voltage level. However, when the load size (or value) changes abruptly, the output voltage of the voltage regulator may change according to how a circuit of the voltage regulator is implemented or designed. Due to change in output voltage of the voltage regulator, errors may occur in operation of an electronic device which operates based on the output voltage of the voltage regulator.

### SUMMARY

Some example embodiments of the present disclosure relate to a voltage regulator and an operation method thereof in which unintended changes in output voltage of the voltage regulator are reduced and/or minimized.

According to some example embodiments, a voltage regulator may include an error amplifier including a first input terminal receiving a reference voltage, a second input terminal connected to a feedback node, and a first output terminal configured to output a pass gate voltage, and a pass transistor connected between an input voltage and an output node. The pass transistor is configured to operate in response to the pass gate voltage. The voltage regulator also includes a first resistor connected between the output node and the feedback node, a second resistor connected between the feedback node and a ground voltage, and a recovery enhancement circuit configured to control a magnitude of one or more driving currents for the error amplifier, based on an output voltage of the output node.

According to some example embodiments, a method of operating a voltage regulator includes setting a driving current of an error amplifier to a first current. The voltage regulator includes the error amplifier, and the error amplifier is configured to generate a pass gate voltage. The method also includes increasing the driving current to a second current higher than the first current, in response to a difference voltage for an output voltage of the voltage regulator and the pass gate voltage being greater than a first supplement threshold voltage, and decreasing the driving current to the first current in response to the difference voltage being less than a second supplement threshold voltage.

According to some example embodiments, a voltage regulator may include an error amplifier configured to generate a pass gate voltage, a pass transistor connected to an output node and configured to operate in response to the pass gate voltage, and a recovery enhancement circuit configured to increase one or more driving currents of the error amplifier, in response to an overshoot occurring in a voltage level of the output node.

### BRIEF DESCRIPTION OF THE DRAWINGS

FIG. 1 is a block diagram showing implementation of a voltage regulator according to some example embodiments.

FIG. 2 illustrates graphs showing a relationship among load current, pass gate voltage, and output voltage according to a comparative example.

FIG. 3 is a block diagram of the error amplifier of FIG. 1.

FIG. 4 is a circuit diagram of the error amplifier of FIG. 3 according to some example embodiments.

FIG. 5 is a circuit diagram of the error amplifier of FIG. 3 according to some example embodiments.

FIG. 6 is a circuit diagram of a driving current source according to some example embodiments.

FIG. 7 is a graph indicating how the recovery enhancement circuit of FIG. 1 controls the driving current source.

FIG. 8 illustrates graphs showing the relationship among load current, pass gate voltage, output voltage, and driving current according to some example embodiments of the present disclosure.

FIG. 9 is a circuit diagram of the recovery enhancement circuit of FIG. 1 according to some example embodiments.

FIG. 10 is a flowchart of a method of operating a voltage regulator according to some example embodiments of the present disclosure.

FIG. 11 is a block diagram of a voltage regulator according to some example embodiments.

FIG. 12 is a circuit diagram of the recovery enhancement circuit of FIG. 11 according to some example embodiments.

FIG. 13 is a block diagram of a memory system according to some example embodiments.

FIG. 14 is a block diagram of a universal flash storage (UFS) system according to some example embodiments of the present disclosure.

### DETAILED DESCRIPTION OF EXAMPLE EMBODIMENTS

Hereinafter, various embodiments will be described in detail and clearly to such an extent that an ordinary one in the art easily implements the present disclosure. Specific details such as detailed components and structures are merely provided to assist the overall understanding of the various embodiments. Therefore, it should be apparent to those skilled in the art that various changes and modifications of the embodiments described herein may be made without departing from the scope and spirit of the present disclosure. Moreover, descriptions of well-known functions and structures are omitted for clarity and brevity. In the following drawings or in the detailed description, configurations may be connected with any other components except for components illustrated in a drawing or described in the detailed description. The terms described below are terms defined in consideration of the functions of the present disclosure and are not limited to a specific function. The definitions of the terms should be determined based on the contents throughout the specification.

Components that are described in the detailed description with reference to the terms “driver”, “block”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, a microelectromechanical system (MEMS), a passive element, or a combination thereof.

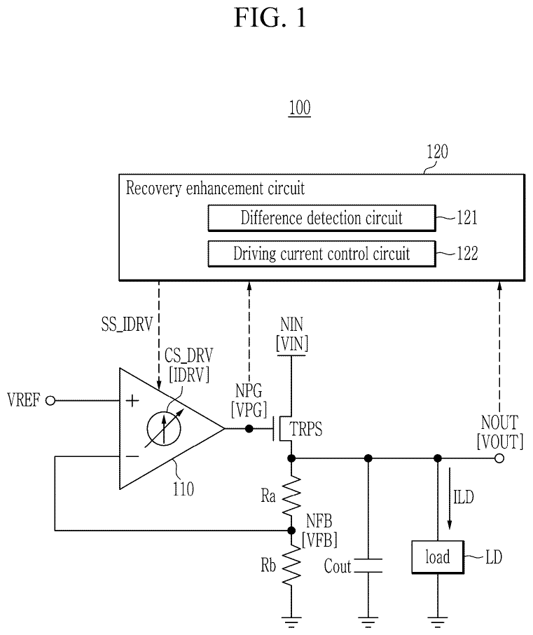

FIG. 1 is a block diagram of a voltage regulator according to some example embodiments. Referring to FIG. 1, a voltage regulator 100 may include an error amplifier 110 and a recovery enhancement circuit 120.

For the sake explanation, the voltage regulator 100 is described as an LDO (low dropout) voltage regulator. However, example embodiments of the present disclosure are not limited to any specific type of voltage regulator 100. For example, the voltage regulator 100 may be implemented as one of various types of voltage regulators, such as a linear regulator, a buck converter, a boost converter, a shunt regulator, or the like.

The voltage regulator 100 may further include a pass transistor TRPS, a first resistor Ra, and a second resistor Rb.

The pass transistor TRPS may be connected between an input node NIN and an output node NOUT. A voltage level of the input node NIN may be an input voltage VIN, and a voltage level of the output node NOUT may be an output voltage VOUT.

A gate terminal of the pass transistor TRPS may be connected to a pass gate node NPG. The pass transistor TRPS may operate based on a pass gate voltage VPG, which is a voltage level of the pass gate node NPG. For example, the pass transistor TRPS may control amount of charge supplied between the input node NIN and the output node NOUT in response to the pass gate voltage VPG.

For the sake of explanation, FIG. 1 illustrates an example in which the pass transistor TRPS is implemented as an NMOS (n-type channel metal-oxide-semiconductor) transistor, but example embodiments are not limited thereto. For example, the pass transistor TRPS may be implemented as a p-type channel metal-oxide-semiconductor PMOS transistor.

The first resistor Ra and the second resistor Rb may be connected in series between the output node NOUT and a ground node. For example, the first resistor Ra may be connected between the output node NOUT and a feedback node NFB, and the second resistor Rb may be connected between the feedback node NFB and the ground node. The voltage level of the feedback node NFB may be referred to as a feedback voltage VFB.

The error amplifier 110 may receive a reference voltage VREF and the feedback voltage VFB. The error amplifier 110 may generate the pass gate voltage VPG based on a difference between the reference voltage VREF and the feedback voltage VFB. The error amplifier 110 may provide the pass gate voltage VPG to the pass gate node NPG.

In some example embodiments, the reference voltage VREF may be provided from a constant voltage source. However, example embodiments of the present disclosure are not limited thereto.

In some example embodiments, the error amplifier 110 may be implemented as an operational amplifier that receives the reference voltage VREF through a non-inverting input terminal and receives the feedback voltage VFB through an inverting input terminal. However, example embodiments of the present disclosure are not limited thereto. For example, an implementation scheme or of the error amplifier 110 may vary depending on the type of the pass transistor TRPS.

The feedback voltage VFB may be determined based on a resistance ratio of the first resistor Ra and the second resistor Rb, and the output voltage VOUT. The pass gate voltage VPG may be generated based on the feedback voltage VFB. The output voltage VOUT may be adjusted based on the pass gate voltage VPG. In this way, the output voltage VOUT may be regulated to a value corresponding to the resistance ratio of the first resistor Ra and the second resistor Rb, and a level of the reference voltage VREF.

A load LD may be connected between the output node NOUT and the ground node. The load LD may correspond to one of various types of electronic devices, such as a memory device, a storage device, a processing device, a sensor device, a motor device, etc. However, example embodiments of the present disclosure are not limited to a specific type of load LD.

The current provided to the load LD may be referred to as load current ILD. The load current ILD may change dynamically depending on an operation of the load LD (for example, if the load LD is implemented with (or as) a memory device, the load current ILD may change depending on whether the load LD is performing a read operation or a write operation).

An output capacitor Cout may be connected between the output node NOUT and the ground node. The output capacitor Cout may maintain the output voltage VOUT at a relatively constant value. For example, the output capacitor Cout may maintain the output voltage VOUT at a relatively constant value when no load current ILD occurs or when the load current ILD changes.

However, if the value (e.g., magnitude) of the load current ILD (or the value of the power required from the load LD) changes, for example, abruptly, the voltage level of the output node NOUT may change, for example, unexpectedly or unintentionally. Such a change may cause an error in the operation of the load LD that operates based on the voltage level of the output node NOUT.

For example, when the value of the load current ILD decreases, for example, at a relatively faster rate or abruptly, an overshoot may occur in the voltage level of the output node NOUT. In this case, an overshoot may also occur at the voltage level of the feedback voltage VFB, and the error amplifier 110 may reduce the pass gate voltage VPG based on the feedback voltage VFB to a level which may keep the pass transistor TRPS in turn-off state. Afterwards, the magnitude of the load current ILD may increase, for example, relatively rapidly. However, due to the lowered pass gate voltage VPG, the pass transistor TRPS may remain turned off. In this case, charge transfer between the input node NIN and the output node NOUT is limited or reduced or lower until the pass gate voltage VPG recovers to a value that is relatively higher to turn on the pass transistor TRPS, so a relatively larger undershoot may occur in the voltage level of the output voltage VOUT due to the load current ILD.

On the other hand, according to some example embodiments of the present disclosure, the recovery enhancement circuit 120 may enhance or improve the recovery of the pass gate voltage VPG based on the output voltage VOUT. For example, the recovery enhancement circuit 120 may improve a rate of which the pass gate voltage VPG increases to a voltage level that is relatively higher to turn on the pass transistor TRPS.

For example, in response to an overshoot occurring in the output voltage VOUT, the recovery enhancement circuit 120 may enhance or improve the recovery of the pass gate voltage VPG. In this case, even if the load current ILD increases, for example, at a relatively faster rate or rapidly, the pass gate voltage VPG may recover to a high voltage level that may turn on the pass transistor TRPS more quickly. Therefore, according to some example embodiments of the present disclosure, the undershoot of the output voltage VOUT caused by an increase in the load current ILD while the pass transistor TRPS is turned off may be minimized or reduced.

In the following, for the sake of explanation, example embodiments in which the recovery enhancement circuit 120 determines whether an overshoot has occurred in the output voltage VOUT based on a difference between the output voltage VOUT and the pass gate voltage VPG are described. However, the example embodiments of the present disclosure are not limited to any specific method of how the recovery enhancement circuit 120 determines whether the overshoot has occurred in the output voltage VOUT.

The recovery enhancement circuit 120 may include a difference detection circuit 121 and a driving current control circuit 122.

The difference detection circuit 121 may detect the difference between the pass gate voltage VPG and the output voltage VOUT. For example, the difference detection circuit 121 may detect a difference voltage (hereinafter referred to as “VDIFF”) by subtracting the pass gate voltage VPG from the output voltage VOUT.

The difference detection circuit 121 may determine whether an overshoot has occurred in the output voltage VOUT based on the difference voltage VDIFF. The difference detection circuit 121 may control the driving current control circuit 122 based on the difference voltage VDIFF. For example, the difference detection circuit 121 may generate a supplement current control voltage (hereinafter referred to as “VSCC”) based on the difference voltage VDIFF.

The driving current control circuit 122 may control a driving current source CS_DRV included in the error amplifier 110 according to the control of the difference detection circuit 121. For example, the driving current control circuit 122 may generate a driving current supplement signal SS_IDRV based on the supplement current control voltage VSCC.

The error amplifier 110 may include the driving current source CS_DRV. The driving current source CS_DRV may change a value of a driving current IDRV in response to the driving current supplement signal SS_IDRV. For example, the driving current source CS_DRV may increase the value of the driving current IDRV in response to the driving current supplement signal SS_IDRV.

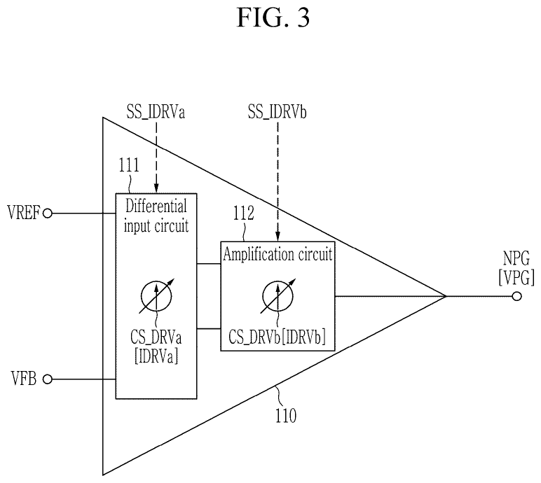

In some example embodiments, the driving current IDRV may be a current used for an operation of the error amplifier 110. The driving current IDRV is discussed with reference to FIGS. 3 to 5 below.

As the driving current IDRV increases, a rate of which the error amplifier 110 provides current to the pass gate node NPG (for example, a speed of which effective charge is provided to the pass gate node NPG) may increase. A length of a transient response of the pass gate voltage VPG according to a change in the feedback voltage VFB may be shortened. Therefore, a speed of which the error amplifier 110 controls the pass gate voltage VPG based on the reference voltage VREF and the feedback voltage VFB may be improved. A length of time required for the pass gate voltage VPG to recover to a level high enough to turn on the pass transistor TRPS may be minimized, reduced, or lowered. Therefore, according to some example embodiments of the present disclosure, the undershoot of the output voltage VOUT may be minimized, reduced, or lowered.

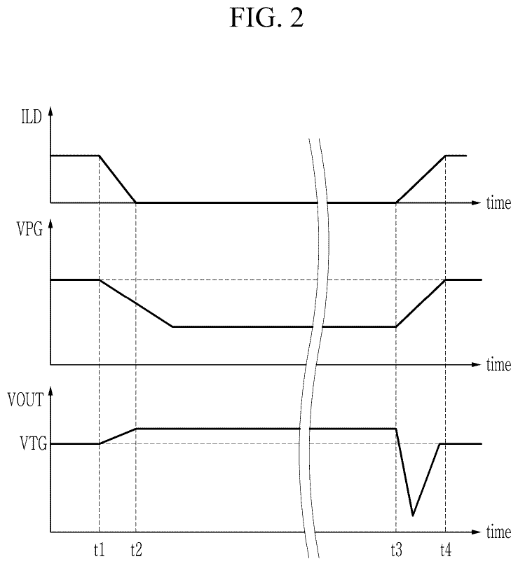

FIG. 2 illustrates graphs showing a relationship among load current, pass gate voltage, and output voltage according to a comparative example. Hereinafter, with reference to FIGS. 1 and 2, the load current ILD, the pass gate voltage VPG, and the output voltage VOUT of a case where the recovery enhancement circuit 120 does not perform the recovery enhancement operation (for example, the driving current supplement signal SS_IDRV is not provided to the error amplifier 110) are described. The horizontal axis of each of the graphs shown in FIG. 2 may represent time, and the vertical axis of each of the graphs shown in FIG. 2 may represent voltage (for example, the pass gate voltage VPG, and the output voltage VOUT) or current (for example, the load current ILD).

Before the first time point t1, the output voltage VOUT may be a target voltage VTG. In the following, it is assumed that the load current ILD before the first time point t1 has a constant value. However, example embodiments of the present disclosure are not limited thereto.

Between the first time point t1 and a second time point t2, the magnitude of the load current ILD may decrease, for example, rapidly. However, since the pass gate voltage VPG is determined by the operation of the error amplifier 110 based on the feedback voltage VFB, the pass gate voltage VPG may decrease relatively slowly compared to the decrease rate of the load current ILD. In this case, even though the value of the load current ILD is reduced, for example, abruptly reduced, the pass transistor TRPS may provide the input voltage VIN to the output node NOUT in response to the pass gate voltage VPG. Accordingly, between the first time point t1 and the second time point t2, the output voltage VOUT may rise (for example, overshoot) to a voltage level higher than the target voltage VTG.

After the second time point t2, the load current ILD may be maintained at a lower value than the first time point t1. For the sake of explanation, below, it is assumed that after the second time point t2, the value of the load current ILD is ‘0’ (for example, a no-load state). However, example embodiments of the present disclosure are not limited thereto.

The output voltage VOUT at the second time point t2 may be higher than the target voltage VTG. In this case, the error amplifier 110 may decrease the pass gate voltage VPG to decrease the output voltage VOUT. Accordingly, the pass gate voltage VPG may further decrease after the second time point t2. In this case, charge transfer between the input node NIN and the output node NOUT may be blocked or reduced, and the output voltage VOUT is maintained by the output capacitor Cout, therefore the output voltage VOUT may be maintained in an overshoot state even after the second time point t2.

In this way, if the no-load state (or low-load state) is maintained after the second time point t2, until the third time point t3 when the load current ILD increases again, the pass gate voltage VPG may be maintained at a low voltage that turns off the pass transistor TRPS and the output voltage VOUT may be maintained in an overshoot state.

Between the third time point t3 and a fourth time point t4, the magnitude of the load current ILD may increase, for example, rapidly. However, since the pass gate voltage VPG at the third time point t3 is a low voltage that turns off the pass transistor TRPS, the load LD may receive current from the output capacitor Cout rather than from the input node NIN. In this case, the output voltage VOUT may continuously decrease due to the discharge of the output capacitor Cout until the pass gate voltage VPG increases to a voltage high enough to turn on the pass transistor TRPS. Therefore, between the third time point t3 and the fourth time point t4, an undershoot may temporarily occur in the output voltage VOUT.

Meanwhile, as the output voltage VOUT decreases, the feedback voltage VFB may also decrease. In this case, the error amplifier 110 may increase the pass gate voltage VPG in response to the feedback voltage VFB. For example, the error amplifier 110 may provide charge to the pass gate node NPG in response to a decrease of the output voltage VOUT (for example, in response to a decrease in the feedback voltage VFB). In this case, the pass transistor TRPS may increase the voltage level of the output node NOUT based on the input voltage VIN in response to the pass gate voltage VPG. Accordingly, at the fourth time point t4, the output voltage VOUT may be recovered to the target voltage VTG.

That is, a value of the undershoot for the output voltage VOUT (for example, the difference between the target voltage VTG and the lowest level of the output voltage VOUT between the third time point t3 and the fourth time point t4) and a time length of the undershoot (for example, a time length for the output voltage VOUT to be recovered to the target voltage VTG after the third time point t3) may be determined depending on rate at which the voltage of the pass gate voltage VPG increases in response to a decrease in the output voltage VOUT. A rate at which the pass gate voltage VPG increases in response to a decrease in the output voltage VOUT may be determined by a rate at which the error amplifier 110 provides charge to the pass gate node NPG (for example, the amount of effective charge provided per unit time). The rate at which the error amplifier 110 provides charge to the pass gate node NPG may be determined based on a current value of the driving current source CS_DRV included in the error amplifier 110. In conclusion, the value of the undershoot for the output voltage VOUT and the time length of the undershoot may be determined based on the current value of the driving current source CS_DRV included in the error amplifier 110. However, as the driving current source CS_DRV generates higher driving current IDRV, a power consumption of the voltage regulator 100 may increase.

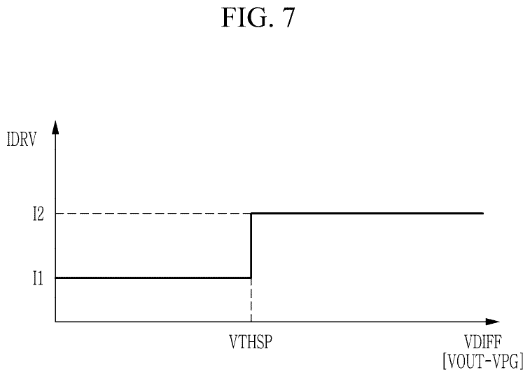

The recovery enhancement circuit 120 according to some example embodiments of the present disclosure may adjust the value of the driving current IDRV adaptively. In this case, the power consumption while the voltage regulator 100 is operating normally may be minimized or reduced, and undershoot of the output voltage VOUT may be minimized or reduced even when the load current ILD changes at a relatively higher rate. The operation scheme of the recovery enhancement circuit 120 is described with reference to FIGS. 7 to 9 below.

FIG. 3 is a block diagram of the error amplifier of FIG. 1. Referring to FIG. 3, with continued reference to FIGS. 1 and 2, the error amplifier 110 may include a differential input circuit 111 and an amplification circuit 112.

The differential input circuit 111 may receive the reference voltage VREF and the feedback voltage VFB. The differential input circuit 111 may control the amplification circuit 112 based on the reference voltage VREF and the feedback voltage VFB.

The amplification circuit 112 may generate an output voltage (for example, pass gate voltage VPG) corresponding to a result of amplifying a difference between the reference voltage VREF and the feedback voltage VFB in response to the control of the differential input circuit 111.

The error amplifier 110 may include one or more driving current sources CS_DRV. For example, at least one of the differential input circuit 111 and the amplification circuit 112 may include one or more driving current sources CS_DRV. For the sake of explanation, FIG. 3 illustrates some example embodiments in which the differential input circuit 111 includes a driving current source CS_DRVa and the amplification circuit 112 includes a driving current source CS_DRVb, but example embodiments of the present disclosure are not limited by the number of driving current sources CS_DRV that are included in each of the differential input circuit 111 and the amplification circuit 112.

The differential input circuit 111 may operate based on the driving current source CS_DRVa. For example, the differential input circuit 111 may control the amplification circuit 112 based on a driving current IDRVa generated by the driving current source CS_DRVa.

The amplification circuit 112 may operate based on the driving current source CS_DRVb. For example, the amplification circuit 112 may generate a pass gate voltage VPG based on a driving current IDRVb generated by the driving current source CS_DRVb.

The driving current control circuit 122 may provide the driving current supplement signal SS_IDRV to one or more of the driving current sources CS_DRV included in the error amplifier 110. For example, the driving current control circuit 122 may provide the driving current supplement signal SS_IDRVa to the driving current source CS_DRVa, and may provide the driving current supplement signal SS_IDRVb to the driving current source CS_DRVb.

The driving current source CS_DRVa may increase the driving current IDRVa in response to the driving current supplement signal SS_IDRVa. The driving current source CS_DRVb may increase the driving current IDRVb in response to the driving current supplement signal SS_IDRVb. In this case, a rate at which the level of the pass gate voltage VPG changes in response to changes in the reference voltage VREF and the feedback voltage VFB may be improved.

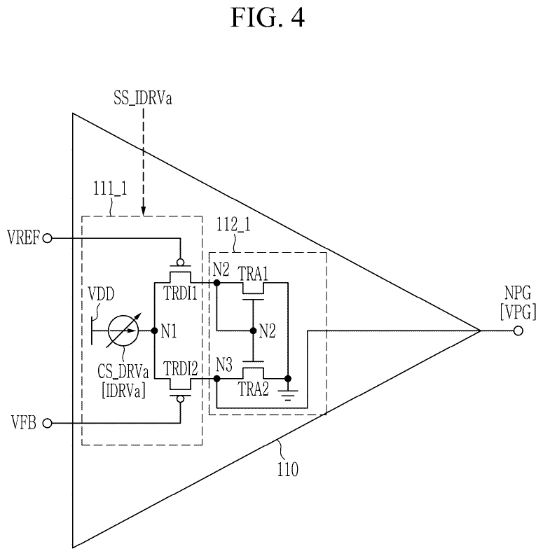

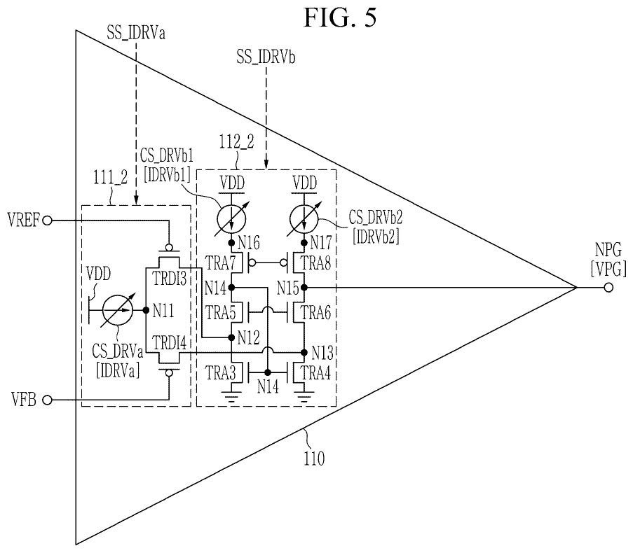

The scope of the present disclosure is not limited to any specific implementation method of the differential input circuit 111 and the amplification circuit 112. For the sake of explanation, the structure or configuration of the differential input circuit 111 and the amplification circuit 112 will be described with reference to FIGS. 4 and 5.

FIG. 4 is a circuit diagram of the error amplifier of FIG. 3 according to some example embodiments. Referring to FIG. 4, with continued reference to FIGS. 1-3, the differential input circuit 111 may be implemented as a differential input circuit 111_1, and the amplification circuit 112 may be implemented as an amplification circuit 112_1. The differential input circuit 111_1 may include the driving current source CS_DRVa, and the amplification circuit 112_1 may not include the driving current source CS_DRVb.

The differential input circuit 111_1 may include a first differential input transistor TRDI1, a second differential input transistor TRDI2, and the driving current source CS_DRVa.

The driving current source CS_DRVa may be connected between the power supply voltage VDD and a first node N1. The driving current source CS_DRVa may provide the driving current IDRVa to the first node N1. The driving current source CS_DRVa may adjust a value of the driving current IDRVa in response to the driving current supplement signal SS_IDRVa.

The first differential input transistor TRDI1 may be connected between the first node N1 and a second node N2. A gate terminal of the first differential input transistor TRDI1 may receive the reference voltage VREF. The second differential input transistor TRDI2 may be connected between the first node N1 and a third node N3. A gate terminal of the second differential input transistor TRDI2 may receive the feedback voltage VFB.

In some example embodiments, a ratio at which the driving current IDRVa is distributed to each of the second node N2 and the third node N3 may be determined based on the relative magnitudes of the feedback voltage VFB and the reference voltage VREF. That is, the current flowing through the first differential input transistor TRDI1 and the current flowing through the second differential input transistor TRDI2 may be determined based on the feedback voltage VFB and the reference voltage VREF.

The amplification circuit 112_1 may include a first amplification transistor TRA1 and a second amplification transistor TRA2.

The first amplification transistor TRA1 may be connected between the second node N2 and the ground voltage. A gate terminal of the first amplification transistor TRA1 may be connected to the second node N2. The second amplification transistor TRA2 may be connected between the third node N3 and ground voltage. A gate terminal of the second amplification transistor TRA2 may be connected to the second node N2.

The third node N3 may be connected to the output terminal of the error amplifier 110. For example, a third node N3 may be connected to the pass gate node NPG.

As a value of the driving current IDRVa increases, an amount of charge flowing through the first differential input transistor TRDI1 and the second differential input transistor TRDI2 may increase. The pass gate voltage VPG may be recovered with a higher rate between the third time point t3 and the fourth time point t4 described above, and thus the undershoot of the output voltage VOUT may be minimized or are reduced.

In some example embodiments, the first differential input transistor TRDI1 and the second differential input transistor TRDI2 may be implemented as PMOS transistors, and the first amplification transistor TRA1 and the second amplification transistor TRA2 may be implemented as NMOS transistors. However, example embodiments of the present disclosure are not limited to any specific type of transistor included in the error amplifier 110.

For the sake of explanation, some example embodiments in which the differential input circuit 111_1 includes one driving current source CS_DRVa is representatively described in FIG. 4, but the example embodiments of the present disclosure are not limited thereto. For example, the differential input circuit 111_1 may not include a driving current source CS_DRVa or may include two or more driving current sources CS_DRVa. In some example embodiments, when the differential input circuit 111_1 includes two or more driving current sources CS_DRVa, the driving current control circuit 122 may provide the driving current supplement signal SS_IDRVa to some or all of the driving current sources CS_DRVa included in the differential input circuit 111_1.

FIG. 5 is a circuit diagram of the error amplifier of FIG. 3 according to some example embodiments. Referring to FIG. 5, with continued reference to FIGS. 1-4, the differential input circuit 111 may be implemented as a differential input circuit 111_2, and the amplification circuit 112 may be implemented as an amplification circuit 112_2. The differential input circuit 111_2 may include a driving current source CS_DRVa, and the amplification circuit 112_2 may include a first driving current source CS_DRVb1 and a second driving current source CS_DRVb2.

The differential input circuit 111_2 may include a third differential input transistor TRDI3, a fourth differential input transistor TRDI4, and the driving current source CS_DRVa. The driving current source CS_DRVa may adjust the value of the driving current IDRVa in response to the driving current supplement signal SS_IDRVa.

The driving current source CS_DRVa may be connected between the power supply voltage VDD and an eleventh node N11. The third differential input transistor TRDI3 may be connected between the eleventh node N11 and a twelfth node N12. A gate terminal of the third differential input transistor TRDI3 may receive the reference voltage VREF. The fourth differential input transistor TRDI4 may be connected between the eleventh node N11 and a thirteenth node N13. A gate terminal of the fourth differential input transistor TRDI4 may receive the feedback voltage VFB. Functions and operations of components included in the differential input circuit 111_2 are similar to the functions and operations of the components included in the differential input circuit 111_1, so a detailed description is omitted.

The amplification circuit 112_2 may include third to eighth amplification transistors TRA3 to TRA8, the first driving current source CS_DRVb1, and the second driving current source CS_DRVb2.

The third amplification transistor TRA3 may be connected between the twelfth node N12 and the ground voltage. The fourth amplification transistor TRA4 may be connected between the thirteenth node N13 and the ground voltage. Gate terminals of the third and fourth amplification transistors TRA3, TRA4 may be connected to a fourteenth node N14.

The fifth amplification transistor TRA5 may be connected between the twelfth node N12 and the fourteenth node N14. The sixth amplification transistor TRA6 may be connected between the thirteenth node N13 and the fifteenth node N15. Gate terminals of the fifth and sixth amplification transistors TRA5, TRA6 may be connected to each other.

The seventh amplification transistor TRA7 may be connected between the fourteenth node N14 and the sixteenth node N16. The eighth amplification transistor TRA8 may be connected between the fifteenth node N15 and the seventeenth node N17. Gate terminals of the seventh and eighth amplification transistors TRA7, TRA8 may be connected to each other. The fifteenth node N15 may be connected to an output terminal of the error amplifier 110. For example, the fifteenth node N15 may be connected to the pass gate node NPG.

The first driving current source CS_DRVb1 may be connected between the power supply voltage VDD and the sixteenth node N16. The first driving current source CS_DRVb1 may provide the first driving current IDRVb1 to the sixteenth node N16. The first driving current source CS_DRVb1 may adjust a value of the first driving current IDRVb1 in response to the driving current supplement signal SS_IDRVb.

The second driving current source CS_DRVb2 may be connected between the power supply voltage VDD and the seventeenth node N17. The second driving current source CS_DRVb2 may provide a second driving current IDRVb2 to the seventeenth node N17. The second driving current source CS_DRVb2 may adjust a value of the second driving current IDRVb2 in response to the driving current supplement signal SS_IDRVb.

In some example embodiments, magnitudes of the first driving current IDRVb1 and the second driving current IDRVb2 may be same each other. In this case, the driving current control circuit 122 may collectively control the first driving current IDRVb1 and the second driving current IDRVb2 based on the driving current supplement signal SS_IDRVb. However, example embodiments of the present disclosure are not limited thereto. For the sake of concise explanation, example embodiments in which the first driving current source CS_DRVb1 and the second driving current source CS_DRVb2 share the driving current supplement signal SS_IDRVb are representatively described in FIG. 5, but the driving current control circuit 122 may control only some (not all) of the two or more driving current sources CS_DRVb included in the amplification circuit 112_2 (for example, control only the second driving current source CS_DRVb2), or may independently control the two or more driving current sources CS_DRVb included in the amplification circuit 112_2.

When one or more of the driving current IDRVa, the first driving current IDRVb1, and the second driving current IDRVb2 increases, an amount of charge moving between nodes included in the error amplifier 110 may increase according to the change of the feedback voltage VFB. In this case, the pass gate voltage VPG may change with a faster rate depending on change of the feedback voltage VFB. Therefore, according to example embodiments of the present disclosure, the pass gate voltage VPG may be recovered with a relatively faster rate between the third time point t3 and the fourth time point t4 described above, and thus the undershoot of the output voltage VOUT may be minimized or reduced.

In some example embodiments, the third and fourth differential input transistors TRDI3, TRDI4 and the seventh and eighth amplification transistors TRA7, TRA8 may be implemented as PMOS transistors; and the third to sixth amplification transistors TRA3 to TRA6 may be implemented as NMOS transistors. However, example embodiments of the present disclosure are not limited to any specific type of transistor included in the error amplifier 110.

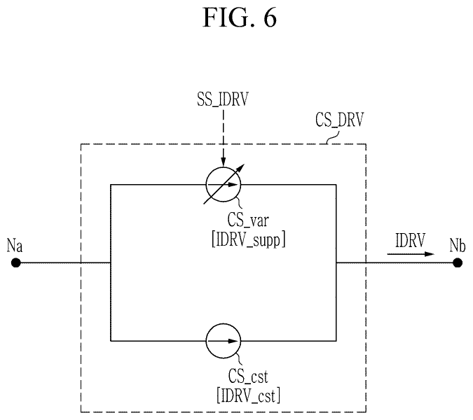

FIG. 6 is a circuit diagram of a driving current source according to some example embodiments. Hereinafter, with reference to FIGS. 1 to 6, an example configuration of one of the driving current sources CS_DRV of FIGS. 3 to 5 is described.

The driving current source CS_DRV may be connected between a first node Na and a second node Nb. In some example embodiments, the first node Na may be provided with the power supply voltage VDD, and the second node Nb may be connected to one of the nodes included in the error amplifier 110.

The driving current source CS_DRV may include a driving constant current source CS_cst and a driving variable current source CS_var. The driving constant current source CS_cst and the driving variable current source CS_var may be connected in parallel between the first node Na and the second node Nb.

The driving constant current source CS_cst may generate a driving constant current IDRV_cst. The driving constant current IDRV_cst may be a constant (or relatively constant) current that may be maintained between the first node Na and the second node Nb.

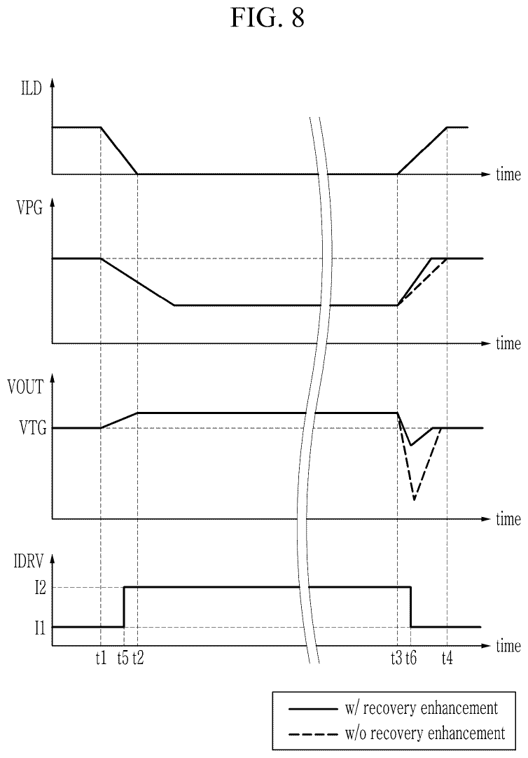

The driving variable current source CS_var may generate a supplement driving current IDRV_supp. The value of the supplement driving current IDRV_supp may be determined based on the driving current supplement signal SS_IDRV. For example, the driving variable current source CS_var may temporarily increase the value of the supplement driving current IDRV_supp in response to the driving current supplement signal SS_IDRV. The manner in which the value of the supplement driving current IDRV_supp is determined is discussed below with reference to FIGS. 7 and 8.

The driving current IDRV may be implemented as the sum of the supplement driving current IDRV_supp and the driving constant current IDRV_cst.

In some example embodiments, the driving current source CS_DRV may further include an operating mode current source connected in parallel with the driving constant current source CS_cst and the driving variable current source CS_var between the first node Na and the second node Nb. The operating mode current source may generate an operating mode current of a value according to an operating mode (for example, high performance mode, low power mode, etc.) of the voltage regulator 100 in response to an operating mode signal. The driving current IDRV may be determined as the sum of the supplement driving current IDRV_supp, the driving constant current IDRV_cst, and the operating mode current. However, other implementations are possible and example embodiments of the present disclosure are not limited to any specific implementation method of the driving current source CS_DRV.

FIG. 7 is a graph indicating how the recovery enhancement circuit of FIG. 1 controls the driving current source. Hereinafter, for the sake of explanation, with reference to FIGS. 1 to 7, example embodiments in which the recovery enhancement circuit 120 controls one driving current source CS_DRV included in the error amplifier 110 based on the difference between the output voltage VOUT and the pass gate voltage VPG will be discussed. The horizontal axis of FIG. 7 may represent the difference voltage VDIFF corresponding to a value obtained by subtracting the pass gate voltage VPG from the output voltage VOUT, and the vertical axis may represent a value of the driving current IDRV.

When the difference voltage VDIFF is smaller than a supplement threshold voltage VTHSP, the recovery enhancement circuit 120 may determine the value of the driving current IDRV as a first current I1. For example, the recovery enhancement circuit 120 may determine the value of the supplement driving current IDRV_supp as ‘0’ based on the driving current supplement signal SS_IDRV. In this case, the value of the driving current IDRV may be determined as the first current I1 corresponding to the value of the driving constant current IDRV_cst.

When the difference voltage VDIFF is greater than the supplement threshold voltage VTHSP, the recovery enhancement circuit 120 may determine the value of the driving current IDRV as the second current I2. For example, the recovery enhancement circuit 120 may determine the value of the supplement driving current IDRV_supp to be a value greater than ‘0’ based on the driving current supplement signal SS_IDRV. In this case, the value of the driving current IDRV may be larger than the value of the driving constant current IDRV_cst.

For the sake of explanation, FIG. 7 illustrates that the recovery enhancement circuit 120 determines the value of the driving current IDRV as one of the first current I1 and the second current I2 based on the supplement threshold voltage VTHSP, but example embodiments of the present disclosure are not limited thereto. For example, the recovery enhancement circuit 120 may increase the value of the driving current IDRV as the difference voltage VDIFF becomes larger than the supplement threshold voltage VTHSP. In other words, the recovery enhancement circuit 120 may gradually (for example, linearly or logarithmically) increase the value of the supplement driving current IDRV_supp according to the value of the difference voltage VDIFF.

In addition, for the sake of explanation, FIG. 7 representatively describes a scheme in which the recovery enhancement circuit 120 controls one driving current source CS_DRV, but example embodiments of the present disclosure are not limited thereto. For example, the recovery enhancement circuit 120 may control two or more driving current sources CS_DRV included in the error amplifier 110 in a similar manner as described above with reference to FIGS. 3 to 5. In this case, the recovery enhancement circuit 120 may control each of two or more driving current sources CS_DRV included in the error amplifier 110 to generate driving currents IDRV of different values (e.g., magnitudes).

FIG. 8 illustrates graphs showing the relationship among load current, pass gate voltage, output voltage, and driving current according to some example embodiments of the present disclosure. Hereinafter, with reference to FIGS. 1 to 8, it is assumed that the recovery enhancement circuit 120 controls the driving current IDRV of one driving current source CS_DRV. The horizontal axis of each of the graphs shown in FIG. 8 may represent time, and the vertical axis may represent voltage or current.

The graph drawn with dotted lines may correspond to a case where the recovery enhancement circuit 120 does not perform the recovery enhancement operation, and the graph drawn with a solid line may correspond to a case where the recovery enhancement circuit 120 performs the recovery enhancement operation.

The magnitude of the load current ILD may decrease, for example, at a relatively higher rate or abruptly between the first time point t1 and the second time point t2. In this case, as previously described with reference to FIG. 2, the output voltage VOUT may rise to a voltage level higher than the target voltage VTG (for example, overshoot) until the magnitude of the load current ILD increases again, and the pass gate voltage VPG may decrease to a low voltage that turns off the pass transistor TRPS.

When the recovery enhancement circuit 120 performs the recovery enhancement operation, the difference detection circuit 121 may identify the difference voltage VDIFF. At a fifth time point t5 when the difference voltage VDIFF becomes greater than the supplement threshold voltage VTHSP, the difference detection circuit 121 may control the driving current source CS_DRV through the driving current control circuit 122 to increase the driving current IDRV from the first current I1 to the second current I2. In this way, the recovery enhancement circuit 120 may increase the driving current IDRV in response to that the value of the load LD decreases at a relatively higher rate or abruptly. On the other hand, when the recovery enhancement circuit 120 does not perform the recovery enhancement operation, the driving current IDRV may be maintained at (or about) the first current I1.

For the sake of explanation, FIG. 8 illustrates that the fifth time point t5 is a time point between the first time point t1 and the second time point t2, but the example embodiments of the present disclosure are not limited thereto. For example, the fifth time point t5 may be a time point between the second time point t2 and the third time point t3.

Between the third time point t3 and the fourth time point t4, the magnitude of the load current ILD may increase. In this case, similar to what was described above with reference to FIG. 2, the output voltage VOUT may decrease continuously until the pass gate voltage VPG increases to a voltage high enough to turn on the pass transistor TRPS. As a result, undershoot may occur in the output voltage VOUT.

Referring to the graphs shown in dotted lines and the graphs shown in solid lines together, when the recovery enhancement circuit 120 performs the recovery enhancement operation, the pass gate voltage VPG may rise relatively quickly to a voltage high enough to turn on the pass transistor TRPS, compared to when the recovery enhancement circuit 120 does not perform the recovery enhancement operation.

Accordingly, when the recovery enhancement circuit 120 performs the recovery enhancement operation, the value of the undershoot and the time length of the undershoot for the output voltage VOUT that occurs between the third time point t3 and the fourth time point t4 may be reduced, compared to when the recovery enhancement circuit 120 does not perform the recovery enhancement operation. Since the output voltage VOUT may be maintained similar to the target voltage VTG, the probability of an error occurring in the operation of the electronic device corresponding to the load LD may be reduced.

When the recovery enhancement circuit 120 performs the recovery enhancement operation, at the sixth time point t6 when the difference voltage VDIFF becomes smaller than the supplement threshold voltage VTHSP, the difference detection circuit 121 may control the driving current source CS_DRV through the driving current control circuit 122 to reduce the driving current IDRV to the first current I1. In this manner, the recovery enhancement circuit 120 may recover (for example, decrease) the driving current IDRV in response to that the value of the load LD increases. In this case, the power consumption of the voltage regulator 100 may be minimized, reduced, or lowered while the electronic device corresponding to the load LD operates normally.

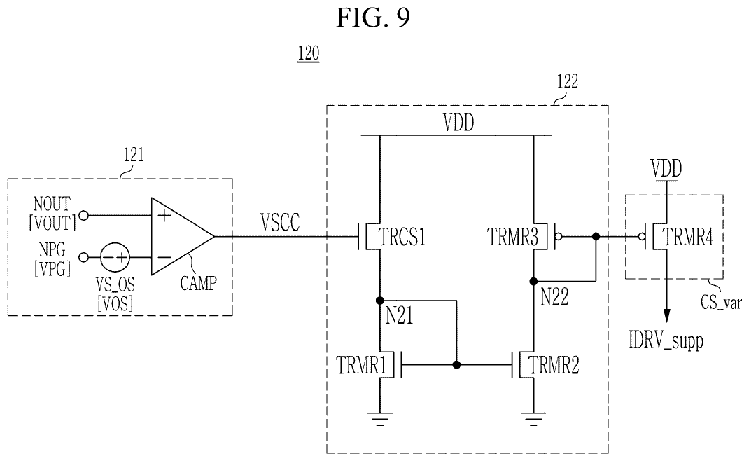

For the sake of explanation, FIGS. 8 and 9 illustrate example embodiments in which the recovery enhancement circuit 120 increases the driving current IDRV when the difference voltage VDIFF becomes greater than the supplement threshold voltage VTHSP and reduces the driving current IDRV when the difference voltage VDIFF becomes less than the supplement threshold voltage VTHSP, but example embodiments of the present disclosure are not limited thereto. For example, the recovery enhancement circuit 120 may be implemented to increase the driving current IDRV when the difference voltage VDIFF becomes greater than a first supplement threshold voltage, and to decrease the driving current IDRV when the difference voltage VDIFF becomes less than a second supplement threshold voltage that is different from the first supplement threshold voltage. Example embodiments of the present disclosure are not limited to any specific operating conditions (for example, triggering condition) of the recovery enhancement circuit 120.

FIG. 9 is a circuit diagram of the recovery enhancement circuit of FIG. 1 according to some example embodiments. Referring to FIGS. 1 to 9, the recovery enhancement circuit 120 may include a difference detection circuit 121 and a driving current control circuit 122.

The difference detection circuit 121 may include a comparison amplifier CAMP and an offset voltage source VS_OS. The non-inverting input terminal of the comparison amplifier CAMP may be connected to the output node NOUT. The comparison amplifier CAMP may receive the output voltage VOUT through the non-inverting input terminal. The inverting input terminal of the comparison amplifier CAMP may be connected to the pass gate node NPG through the offset voltage source VS_OS. The comparison amplifier CAMP may receive, through the inverting input terminal, a voltage higher than the pass gate voltage VPG by the offset voltage VOS.

In some example embodiments, the offset voltage VOS may correspond to the supplement threshold voltage VTHSP.

The comparison amplifier CAMP may output a supplement current control voltage VSCC through an output terminal. The supplement current control voltage VSCC may generate a relatively higher supplement current control voltage VSCC when a value obtained by subtracting the pass gate voltage VPG from the output voltage VOUT is higher than the offset voltage VOS; and may generate a relatively lower supplement current control voltage VSCC when the value obtained by subtracting the pass gate voltage VPG from the output voltage VOUT is lower than the offset voltage VOS. In this way, the comparison amplifier CAMP may generate the supplement current control voltage VSCC based on whether the difference voltage VDIFF is greater than the supplement threshold voltage VTHSP (or offset voltage VOS).

For the sake of explanation, FIG. 9 illustrates example embodiments in which a comparison amplifier CAMP receives the output voltage VOUT through the non-inverting input terminal and receives the voltage higher than the pass gate voltage VPG by the offset voltage VOS through the inverting input terminal, but example embodiments of the present disclosure are not limited to a specific implementation method of the difference detection circuit 121. For example, the comparison amplifier CAMP may be implemented to receive a voltage lower than the output voltage VOUT by an offset voltage VOS through the non-inverting input terminal and to receive the pass gate voltage VPG through the inverting input terminal.

The driving current control circuit 122 may include a first current source transistor TRCS1 and first to third mirroring transistors TRMR1 to TRMR3.

The first current source transistor TRCS1 may be connected between the power supply voltage VDD and a twenty-first node N21. The first current source transistor TRCS1 may provide current to the twenty-first node N21 in response to the supplement current control voltage VSCC. For example, the first current source transistor TRCS1 may provide a relatively larger current to the twenty-first node N21 when the supplement current control voltage VSCC has a higher voltage; and the first current source transistor TRCS1 may provide a relatively smaller current to the twenty-first node N21 when the supplement current control voltage VSCC has a lower voltage.

The first mirroring transistor TRMR1 may be connected between the twenty-first node N21 and the ground voltage. The second mirroring transistor TRMR2 may be connected between the twenty-second node N22 and the ground voltage. Gate terminals of the first mirroring transistor TRMR1 and the second mirroring transistor TRMR2 may be connected to the twenty-first node N21. A current having same (or similar) value as a current generated by the first current source transistor TRCS1 may be mirrored as a current flowing through the second mirroring transistor TRMR2.

The third mirroring transistor TRMR3 may be connected between the twenty-second node N22 and the power supply voltage VDD. A gate terminal of the third mirroring transistor TRMR3 may be connected to the twenty-second node N22.

The driving variable current source CS_var may include a fourth mirroring transistor TRMR4. The source terminal of the fourth mirroring transistor TRMR4 may be connected to the power supply voltage VDD. A gate terminal of the fourth mirroring transistor TRMR4 may be connected to the twenty-second node N22. The driving current control circuit 122 may provide the driving current supplement signal SS_IDRV to the driving current source CS_DRV in a form of a voltage level of the twenty-second node N22. The current flowing through the second mirroring transistor TRMR2 may be mirrored, through the third mirroring transistor TRMR3, as the supplement driving current IDRV_supp which is flowing through the fourth mirroring transistor TRMR4. In other words, the driving current control circuit 122 may generate the supplement driving current IDRV_supp (for example, a current flowing through the second mirroring transistor TRMR2), and the driving variable current source CS_var may mirror the supplement driving current IDRV_supp as a current flowing through the fourth mirroring transistor TRMR4. In this way, the recovery enhancement circuit 120 may control the value of one or more driving currents IDRV.

In some example embodiments, the first current source transistor TRCS1 and the first and second mirroring transistors TRMR1, TRMR2 may be implemented as NMOS transistors. The third and fourth mirroring transistors TRMR3, TRMR4 may be implemented as PMOS transistors. However, example embodiments of the present disclosure are not limited to the specific types of each transistor included in the recovery enhancement circuit 120.

In some example embodiments, a ‘current limiting transistor’ may be further connected between the drain terminal of the second mirroring transistor TRMR2 and the twenty-second node N22. A gate terminal of the ‘current limiting transistor’ may be connected to a bias voltage. In this case, the value of the supplement driving current IDRV_supp may be limited to a certain (or desired or given) value by the current limiting transistor. In this case, a phenomenon of which the supplement driving current IDRV_supp excessively increasing as the difference voltage VDIFF increases may be reduced or prevented. However, example embodiments of the present disclosure are not limited thereto.

For the sake of explanation, FIG. 9 is a representative example in which the recovery enhancement circuit 120 controls the value of the supplement driving current IDRV_supp based on the comparison amplifier CAMP and a current mirror, but example embodiments of the present disclosure are not limited to a specific implementation method of the recovery enhancement circuit 120. For example, the recovery enhancement circuit 120 may be implemented to switch one or more current sources included in the variable current source CS_var based on the supplement current control voltage VSCC.

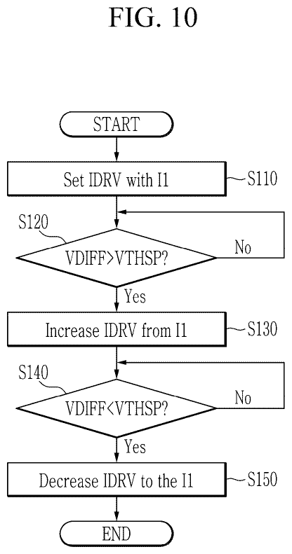

FIG. 10 is a flowchart of a method of operating a voltage regulator according to some example embodiments of the present disclosure. It is understood that additional operations can be provided before, during, and after the operations in FIG. 10, and some of the operations described below can be replaced or eliminated, for additional embodiments of the method. The order of the operations/processes may be interchangeable, or two or more operations can be performed simultaneously. Referring to FIG. 10, with continued reference to FIGS. 1-9, in operation S110, the voltage regulator 100 may setup the driving current IDRV with the first current I1. For example, the recovery enhancement circuit 120 may set the driving current IDRV generated by one driving current source CS_DRV included in the error amplifier 110 with the first current I1.

In operation S120, the voltage regulator 100 may determine whether the difference voltage VDIFF is greater than the supplement threshold voltage VTHSP. If the difference voltage VDIFF is greater than the supplement threshold voltage VTHSP, then operation S130 may be performed. If the difference voltage VDIFF is less than the supplement threshold voltage VTHSP, then operation S120 may be repeated. In this way, the voltage regulator 100 may maintain the driving current IDRV with the first current I1 until the difference voltage VDIFF becomes greater than the supplement threshold voltage VTHSP.

In operation S130, the voltage regulator 100 may increase the driving current IDRV from the first current I1. For example, the recovery enhancement circuit 120 may increase the driving current IDRV generated by one driving current source CS_DRV included in the error amplifier 110 to a second current I2 higher than the first current I1.

In some example embodiments, operation S130 may be performed in response to that the magnitude of the load current ILD decreases. For example, operation S130 may be performed in response to that output voltage VOUT increases and the pass gate voltage VPG decreases as the magnitude of load current ILD decreases.

In operation S140, the voltage regulator 100 may determine whether the difference voltage VDIFF is less than the supplement threshold voltage VTHSP. If the difference voltage VDIFF is less than the supplement threshold voltage VTHSP, then following operation S150 may be performed. If the difference voltage VDIFF is greater than the supplement threshold voltage VTHSP, then operation S140 may be repeated. In this manner, the voltage regulator 100 may maintain the magnitude of the driving current IDRV higher than the first current I1 (for example, maintain to the second current I2) until the difference voltage VDIFF becomes less than the supplement threshold voltage VTHSP. In this case, even if the load current ILD changes, for example, rapidly, the pass gate voltage VPG may be recovered with a relatively higher rate, so that the change in the output voltage VOUT of the voltage regulator 100 may be minimized or reduced.

In operation S150, the voltage regulator 100 may reduce the driving current IDRV to the first current I1. For example, the recovery enhancement circuit 120 may recover the driving current IDRV generated by one driving current source CS_DRV included in the error amplifier 110 to the value previously set in the operation S110. The method mya thus reduce the power consumption of the voltage regulator 100.

In some example embodiments, operation S150 may be performed in response to the magnitude of the load current ILD increasing. For example, operation S150 may be performed in response to output voltage VOUT decreasing as the magnitude of load current ILD increases.

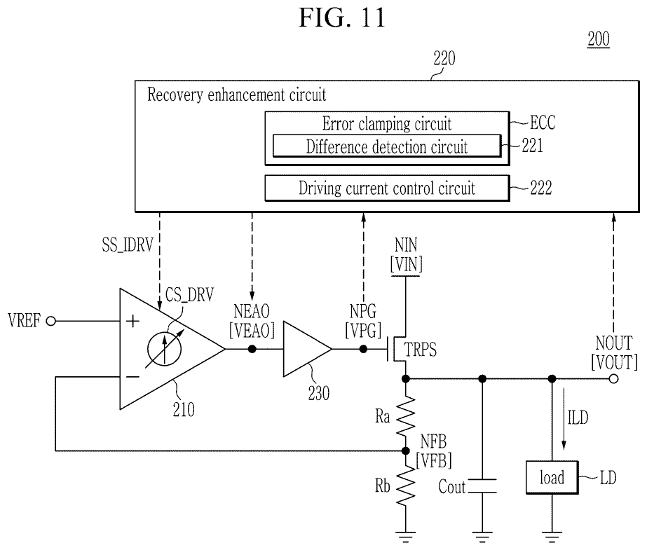

FIG. 11 is a block diagram of a voltage regulator according to some example embodiments. Referring to FIG. 11, and with continued reference to FIGS. 1-10, the voltage regulator 200 may include an error amplifier 210, a recovery enhancement circuit 220, a buffer circuit 230, a pass transistor TRPS, a first resistor Ra, a second resistor Rb, and an output capacitor Cout. The configuration and operation of the error amplifier 210, the pass transistor TRPS, the first resistor Ra, the second resistor Rb, and the output capacitor Cout are similar to those described above with reference to FIGS. 1 to 11, so a detailed description is omitted for the sake of brevity.

The buffer circuit 230 may be connected between an output terminal of an error amplifier 210 (hereinafter, referred to as an error amplifier output node NEAO) and a pass gate node NPG. For example, the buffer circuit 230 may provide a pass gate voltage VPG to the pass gate node NPG, which is generated by buffering an error amplifier output voltage VEAO provided from the error amplifier output node NEAO.

The recovery enhancement circuit 220 may include an error clamping circuit ECC and a driving current control circuit 222. The error clamping circuit ECC may include a difference detection circuit 221.

The error clamping circuit ECC may control the error amplifier output voltage VEAO based on the pass gate voltage VPG and the output voltage VOUT. For example, the error clamping circuit ECC may detect the difference between the pass gate voltage VPG and the output voltage VOUT based on the difference detection circuit 221. The error clamping circuit ECC may provide current to the error amplifier output node NEAO based on the difference voltage VDIFF.

The driving current control circuit 222 may provide, to the error amplifier 210, a supplement driving current IDRV_supp corresponding to a current provided to the error amplifier output node NEAO.

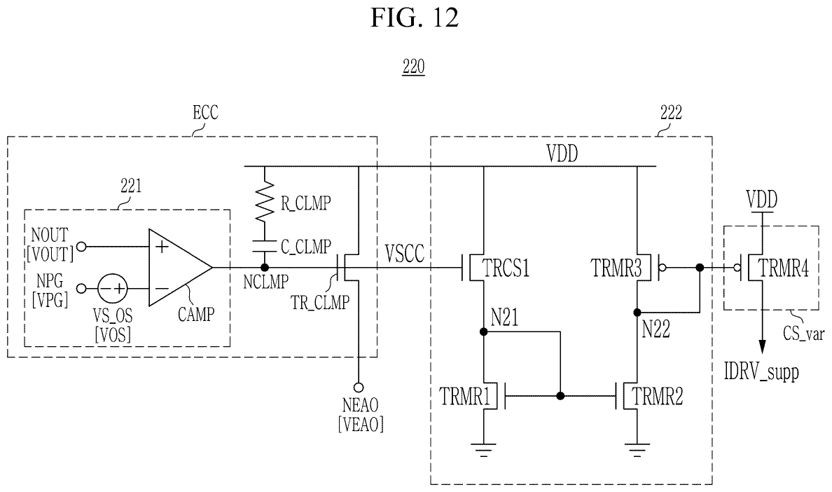

FIG. 12 is a circuit diagram of the recovery enhancement circuit of FIG. 11 according to some example embodiments. Referring to FIG. 12, with continued reference to FIGS. 1-11, the recovery enhancement circuit 220 may include an error clamping circuit ECC and the driving current control circuit 222.

The error clamping circuit ECC may include the difference detection circuit 221, a clamp transistor TR_CLMP, a clamp resistor R_CLMP, and a clamp capacitor C_CLMP.

The output terminal of the difference detection circuit 221 may be connected to a clamp node NCLMP. A voltage level of the clamp node NCLMP may be referred to as a supplement current control voltage VSCC. The configuration and operation of the difference detection circuit 221 are similar to the configuration and operation of the difference detection circuit 121 described above with reference to FIG. 9, so a detailed description is omitted.

The clamp resistor R_CLMP and the clamp capacitor C_CLMP may be connected between the power supply voltage VDD and a clamp node NCLMP. In some example embodiments, the clamp resistor R_CLMP and the clamp capacitor C_CLMP may be individual or discrete components that are connected between the power supply voltage VDD and the clamp node NCLMP. However, example embodiments of the present disclosure are not limited thereto, and the clamp resistor R_CLMP may be a parasitic resistance, and the clamp capacitor C_CLMP may be a parasitic capacitance.

The clamp transistor TR_CLMP may be connected between the power supply voltage VDD and the error amplifier output node NEAO. The clamp transistor TR_CLMP may provide current to the error amplifier output node NEAO in response to the supplement current control voltage VSCC. For example, the clamp transistor TR_CLMP may adjust, in response to the supplement current control voltage VSCC, the error amplifier output voltage VEAO by providing current to the error amplifier output node NEAO.

The driving current control circuit 222 may generate a supplement driving current IDRV_supp based on the supplement current control voltage VSCC. For example, the driving current control circuit 222 may include a first current source transistor TRCS1 and first to third mirroring transistors TRMR1 to TRMR3.

A gate terminal of the first current source transistor TRCS1 may be connected to the clamp node NCLMP. A value of the current generated by the first current source transistor TRCS1 may correspond to a value of the current generated by the clamp transistor TR_CLMP.

The driving variable current source CS_var may include a fourth mirroring transistor TRMR4. The supplement driving current IDRV_supp generated by the driving current source CS_DRV may be determined based on the current generated by the first current source transistor TRCS1. The specific configuration and operating principle of the driving current control circuit 222 are same as or similar in some respects to the configuration and operation of the driving current control circuit 222 described above with reference to FIG. 9, so a detailed description is omitted.

According to the embodiments of FIGS. 11 and 12, the recovery enhancement circuit 220 may be implemented based on components of an error clamping circuit ECC. Since components of the error clamping circuit ECC may also be used for the recovery enhancement operation, the production efficiency of the voltage regulator 200 may be improved.

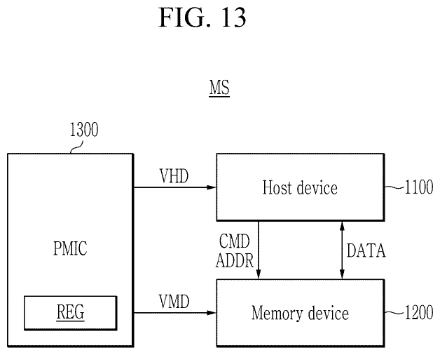

FIG. 13 is a block diagram of a memory system according to some example embodiments. Referring to FIG. 13, with continued reference to FIGS. 1-12, a memory system MS may include a host device 1100, a memory device 1200, and a PMIC (power management integrated circuit) 1300.

The host device 1100 may control the memory device 1200 by issuing a command CMD and an address ADDR. For example, the host device 1100 may read data DATA from the memory device 1200 or store data DATA in the memory device 1200 by issuing command CMD and address ADDR.

In some example embodiments, the host device 1100 may be implemented as one of various types of electronic devices, such as a processor, an application processor (AP), a system on chip (SoC), and the like.

In some example embodiments, the memory device 1200 may be implemented as a nonvolatile memory device such as a flash memory. However, example embodiments of the present disclosure are not limited thereto, and the memory device 1200 may be implemented as a volatile memory device such as a DRAM (dynamic random access memory) device, an SRAM (static random access memory) device, etc.

The PMIC 1300 may include one or more voltage regulators REG. The PMIC 1300 may generate a host driving voltage VHD and a memory driving voltage VMD based on one or more voltage regulators REG. The host driving voltage VHD and the memory driving voltage VMD may correspond to the output voltage VOUT generated by the voltage regulator 100 or the voltage regulator 200 as described above with reference to FIGS. 1 to 12. The PMIC 1300 may provide the host driving voltage VHD to the host device 1100 and the memory driving voltage VMD to the memory device 1200. However, example embodiments of the present disclosure are not limited thereto, and the PMIC 1300 may provide driving voltage to only one of the host device 1100 and the memory device 1200.

In some example embodiments, each of the one or more voltage regulators REG may be implemented as the voltage regulator 100 or the voltage regulator 200 as described above with reference to FIGS. 1 to 12. For example, the PMIC 1300 may generate the host driving voltage VHD based on the voltage regulator 100. In this case, the load LD described above with reference to FIGS. 1 to 12 may correspond to the host device 1100. Alternatively, the PMIC 1300 may generate the memory driving voltage VMD based on the voltage regulator 100. In this case, the load LD described above with reference to FIGS. 1 to 12 may correspond to the memory device 1200.

In some example embodiments, when the host driving voltage VHD and the memory driving voltage VMD are generated based on the voltage regulator 100 or the voltage regulator 200 described with reference to FIGS. 1 to 12 above, even if the value of the load LD changes, for example, rapidly, depending on the operation of the host device 1100 or the memory device 1200, the voltage levels of the host driving voltage VHD and the memory driving voltage VMD may be maintained relatively constant. According to some example embodiments of the present disclosure, undershoot of the host driving voltage VHD and the memory driving voltage VMD may be minimized or reduced. An operation error of the host device 1100 due to an unintended or unexpected fluctuation of the host driving voltage VHD may be minimized or reduced, and an operation error of the memory device 1200 due to an unintended or unexpected fluctuation of the memory driving voltage VMD may be minimized or reduced.

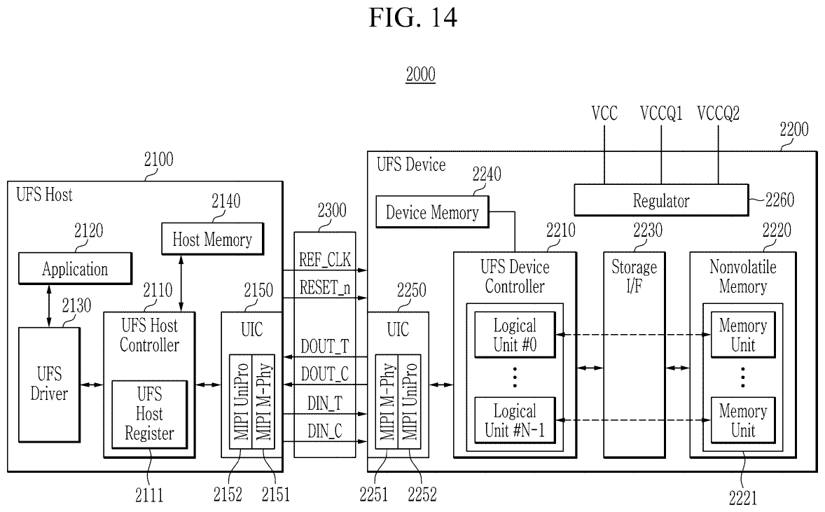

FIG. 14 is a block diagram of a universal flash storage (UFS) system according to some example embodiments of the present disclosure. Referring to FIG. 14, with continued reference to FIGS. 1-13, the UFS system 2000 may be a system that is based on a UFS standard presented by Joint Electron Device Engineering Council (JEDEC). The UFS system 2000 may include a UFS host 2100, a UFS device 2200, and a UFS interface 2300.

The UFS host 2100 and the UFS device 2200 may be interconnected through the UFS interface 2300. The UFS host 2100 may be implemented as the host device 1100 of FIG. 13. The UFS device 2200 may be implemented as the memory device 1200 of FIG. 13. The UFS system 2000 may correspond to the memory system MS described above with reference to FIG. 13.

The UFS host 2100 may include a UFS host controller 2110, an application 2120, a UFS driver 2130, host memory 2140, and a UFS interconnect (UIC) layer 2150. The UFS device 2200 may include a UFS device controller 2210, a nonvolatile memory 2220, a storage interface 2230, a device memory 2240, a UIC layer 2250, and a regulator 2260.

The nonvolatile memory 2220 may include a plurality of memory units 2221. The plurality of memory units 2221 may include V-NAND flash memory having a 2D structure or a 3D structure. However, example embodiments of the present disclosure are not limited thereto, and the plurality of memory units 2221 may include other types of nonvolatile memory, such as phase-change random access memory (PRAM) and/or resistive random access memory (RRAM).

The UFS device controller 2210 and the nonvolatile memory 2220 may be connected to each other through the storage interface 2230. The storage interface 2230 may comply with (or may be based on) standard specifications such as Toggle or Open NAND Flash Interface (ONFI).

The application 2120 may refer to a program that communicates with the UFS device 2200 for utilizing functions of the UFS device 2200. The application 2120 may transfer input/output request for the UFS device 2200 to the UFS driver 2130. The input/output request may refer to a data read request, a store data request, or a discard data request, but example embodiments of the present disclosure are not limited thereto.

The UFS driver 2130 may manage the UFS host controller 2110 through a UFS-HCI (UFS-host controller interface). The UFS driver 2130 may convert the input/output requests generated by the application 2120 into UFS commands defined by the UFS standard, and may transmit the converted UFS commands to the UFS host controller 2110. Single I/O request may be converted into a plurality of UFS commands. The UFS commands may be commands defined by Small Computer System Interface (SCSI) standard, but example embodiments of the present disclosure are not limited thereto, and the UFS commands may be dedicated commands for the UFS standard.

The UFS host controller 2110 may transmit the UFS command converted by the UFS driver 2130 to the UIC layer 2250 of the UFS device 2200 through the UIC layer 2150 and the UFS interface 2300. In this process, the UFS host register 2111 of the UFS host controller 2110 may support role as a command queue.

The UIC layer 2150 on the UFS host 2100 side may include MIPI M-PHY 2151 and MIPI UniPro 2152. The UIC layer 2250 on the UFS device 2200 side may include MIPI M-PHY 2251 and MIPI UniPro 2252.

The UFS interface 2300 may include a line transmitting a reference clock REF_CLK, a line transmitting a hardware reset signal RESET_n for the UFS device 2200, a pair of lines transmitting a differential input signal pair DIN_T DIN_C, and a pair of lines transmitting a pair of differential output signals DOUT_T, DOUT_C.

A frequency of the reference clock REF_CLK provided from the UFS host 2100 to the UFS device 2200 may be one of four values: 19.2 MHz, 26 MHz, 38.4 MHz, and 52 MHz. However, example embodiments of the present disclosure are not limited thereto.

The UFS host 2100 may change the frequency value of the reference clock REF_CLK even while performing data transmission or reception operations with the UFS device 2200. The UFS device 2200 may generate clocks of various frequencies from the reference clock REF_CLK provided from the UFS host 2100 using an electronic circuit such as a PLL (phase-locked loop). Additionally, the UFS host 2100 may also set a value of data rate between the UFS host 2100 and the UFS device 2200 based on a frequency value of the reference clock REF_CLK. The value of the data rate may be determined according to the frequency value of the reference clock REF_CLK.

The UFS interface 2300 may support a plurality of lanes, and each lane may be implemented as a differential line pair. For example, the UFS interface 2300 may include one or more receive lanes and one or more transmit lanes. In FIG. 14, one pair of lines transmitting the pair of differential input signals DIN_T, DIN_C may correspond to a receiving lane of the UFS device 2200; and one pair of lines transmitting a pair differential output signals DOUT_T, DOUT_C may correspond to a transmitting lane of the UFS device 2200. For the sake of explanation, one transmit lane and one receive lane are illustrated in FIG. 14, but example embodiments of the present disclosure are not limited to any particular number of transmit lanes and receive lanes.

The receiving lane and transmitting lane may transmit data in a serial communication manner. Since the receiving lanes and transmitting lanes are independent of each other, the UFS host 2100 and the UFS device 2200 may communicate with each other in a full-duplex manner. For example, the UFS device 2200 may transmit data to the UFS host 2100 through a transmit lane while receiving data from the UFS host 2100 through a receive lane.

Control data, such as commands provided from the UFS host 2100 to the UFS device 2200, may be transmitted through same lane as user data transmitted through the UFS interface 2300 when the UFS host 2100 performs input/output operations for the UFS device 2200. Accordingly, there may be no separate lanes for data transmission between the UFS host 2100 and the UFS device 2200 other than a pair of receiving lanes and a pair of transmitting lanes.

The UFS device controller 2210 may control overall operations of the UFS device 2200. The UFS device controller 2210 may manage nonvolatile memory 2220 based on LU(logical unit).

In some example embodiments, a number of LUs managed by the UFS device controller 2210 may be 8. However, example embodiments of the present disclosure are not limited thereto.

The UFS device controller 2210 may include a flash translation layer (FTL). The UFS device controller 2210 may convert logical address (for example, logical block address (LBA)) transmitted from the UFS host 2100 into physical address (for example, physical block address (PBA)) by using address mapping information of the FTL.

In some example embodiments, a logical block for storing user data in the UFS system 2000 may have a size (or capacity) within a specific or desired or given range. For example, a minimum size (or capacity) of the logical block may be 4 Kbytes.

When a command issued from the UFS host 2100 is provided to the UFS device 2200 through the UIC layer 2250, the UFS device controller 2210 may perform corresponding operation thereto and then may transmit a completion response to the UFS host 2100.

For example, when the UFS host 2100 stores user data in the UFS device 2200, the UFS host 2100 may transmit a data storage command to the UFS device 2200. The UFS device 2200 may provide a response (for example, a ready-to-transfer response) to the UFS host 2100 indicating that the UFS device 2200 is ready to receive the user data. The UFS host 2100 may transfer the user data to the UFS device 2200. The UFS device controller 2210 may temporarily store the user data in the device memory 2240; and may store the user data temporarily stored in the device memory 2240 in the nonvolatile memory 2220 based on the address mapping information of the FTL.

For another example, when the UFS host 2100 reads user data from the UFS device 2200, the UFS host 2100 may transmit a data read command to the UFS device 2200. The UFS device controller 2210 may read the user data from the nonvolatile memory 2220 in response to the data read command, and may temporarily store the read user data in the device memory 2240, and then may transmit the user data in the device memory 2240 to the UFS host 2100.

The UFS host 2100 may store commands to be transmitted to the UFS device 2200 in a command queue (for example, the UFS host register 2111) and provide such commands to the UFS device 2200 sequentially. The UFS host 2100 may transmit another command queued in the command queue to the UFS device 2200 even if the previously transmitted command is still being processed by the UFS device 2200 (for example, before receiving a completion response for the previously transmitted command from the UFS device 2200). In this case, the UFS device 2200 may be implemented to receive another command even while processing a previously transmitted command.

In some example embodiments, a maximum number of commands that may be stored in the command queue (for example, queue depth) may be 32. However, example embodiments of the present disclosure are not limited thereto.

In some example embodiments, the command queue may be implemented as a circular queue type that stores commands based on a head pointer and a tail pointer. However, example embodiments of the present disclosure are not limited thereto.

The UFS device 2200 may receive various types of power voltages such as “VCC”, “VCCQ”, “VCCQ2”, etc. “VCC” may be the main power voltage of the UFS device 2200 and may have a level of 2.4 V (or about 2.4 V) to 3.6 V (or about 3.6 V). “VCCQ” may be a low operating voltage for the UFS device 2200 (for example, a voltage to be provided to the UFS device controller 2210) and may have a level of 1.14 V (or about 1.14 V) to 1.26 V (or about 1.26 V). “VCCQ 2” may be an operating voltage between “VCC” and “VCCQ” (for example, a voltage to be provided to an input/output interface such as MIPI M-PHY 2251) and may have a level of 1.7 V (or about 1.7 V) to 1.95 V (or about 1.95 V). These power voltages may be provided to each component of the UFS device 2200 through the regulator 2260.

In some example embodiments, one or more of the various types of power supply voltages, such as “VCC”, “VCCQ”, “VCCQ2”, etc., may be provided from the voltage regulator 100 or the voltage regulator 200 described with reference to FIGS. 1 to 12 above. For example, “VCC” may be generated from the voltage regulator 100. Even if the UFS device 2200 transitions from a state requiring a high load current ILD, such as a read operation or a write operation, to a state requiring a low load current ILD, such as an idle state or a sleep mode, and then transitions again to a state requiring a high load current ILD, the undershoot of the voltage level of “VCC” may be minimized or reduced. In other words, when “VCC” is provided from the voltage regulator 100, “VCC” may be maintained with constant voltage level even if the load current ILD required by the UFS device 2200 changes abruptly. The voltage provided to each component of the UFS device 2200 may be maintained relatively consistent, and thus the operational stability of the UFS device 2200 may be improved.

According to some example embodiments, a memory system includes a power management integrated circuit (PMIC) including a first voltage regulator configured to generate a host driving voltage and a second voltage regulator configured to generate a memory driving voltage; a host device connected to the PMIC and configured to receive the host driving voltage; and a memory device connected to the PMIC and configured to receive the memory driving voltage. Each of the first voltage regulator and the second voltage regulator includes, an error amplifier including a first input terminal configured to receive a reference voltage, a second input terminal connected to a feedback node, and a first output terminal configured to output a pass gate voltage; a pass transistor connected between an input voltage and an output node, wherein the pass transistor is configured to operate in response to the pass gate voltage; a first resistor connected between the output node and the feedback node; a second resistor connected between the feedback node and a ground voltage; and a recovery enhancement circuit configured to provide one or more driving currents to the error amplifier and configured to control a magnitude of the one or more driving currents based on an output voltage of the output node, and the output voltage corresponds to one of the host driving voltage or the memory driving voltage. According to some example embodiments, the error amplifier comprises a differential input circuit configured to receive the reference voltage and a feedback voltage corresponding to the feedback node; and an amplification circuit configured to generate the pass gate voltage based on a control from the differential input circuit. At least one of the differential input circuit and the amplification circuit includes a first driving current source that is configured to generate a first driving current, the one or more driving currents including the first driving current. According to some example embodiments, the first driving current source is a variable current source configured to operate in response to the control from the recovery enhancement circuit. According to some example embodiments, the recovery enhancement circuit comprises a difference detection circuit configured to generate a supplement current control voltage based on a difference voltage between the output voltage and the pass gate voltage; and a driving current control circuit configured to control a value of the first driving current based on the supplement current control voltage. According to some example embodiments, the driving current control circuit is configured to generate a supplement driving current based on the supplement current control voltage; and provide the supplement driving current to the first driving current source.

As described herein, any devices, systems, modules, portions, units, controllers, circuits, and/or portions thereof according to any of the example embodiments, and/or any portions thereof (including, without limitation, the error amplifier 110, the recovery enhancement circuit 120, the difference detection circuit 121, the driving current control circuit 122, the differential input circuit 111, the amplification circuit 112, the differential input circuit 111_1, the amplification circuit 112_1, the differential input circuit 111_2, the amplification circuit 112_2, the error clamping circuit ECC, the driving current control circuit 222, the difference detection circuit 221, the PMIC (power management integrated circuit) 1300, the UFS host 2100, the UFS device 2200, the UFS interface 2300, the UFS host 2100, the UFS device 2200, the UFS interface 2300, the host device 1100, the UFS device 2200, the UFS host 2100, the UFS host controller 2110, the application 2120, the UFS driver 2130, the host memory 2140, the UFS interconnect (UIC) layer 2150, the UFS device controller 2210, the nonvolatile memory 2220, the storage interface 2230, the device memory 2240, the UIC layer 2250, the regulator 2260, the MIPI M-PHY 2151, the MIPI UniPro 2152, the MIPI M-PHY 2251, the MIPI UniPro 2252, the UFS host register 2111, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Example embodiments are not necessarily mutually exclusive. For example, some example embodiments may include one or more features described with reference to one or more figures, and may also include one or more other features described with reference to one or more other figures.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A voltage regulator, comprising:
an error amplifier including a first input terminal configured to receive a reference voltage, a second input terminal connected to a feedback node, and a first output terminal configured to output a pass gate voltage;
a pass transistor connected between an input voltage and an output node, wherein the pass transistor is configured to operate in response to the pass gate voltage;
a first resistor connected between the output node and the feedback node;
a second resistor connected between the feedback node and a ground voltage; and
a recovery enhancement circuit configured to control a magnitude of one or more driving currents for the error amplifier, based on an output voltage of the output node.

2. The voltage regulator of claim 1, wherein the error amplifier comprises:
a differential input circuit configured to receive the reference voltage and a feedback voltage corresponding to the feedback node; and
an amplification circuit configured to generate the pass gate voltage based on a control from the differential input circuit,
wherein at least one of the differential input circuit and the amplification circuit includes a first driving current source that is configured to generate a first driving current, the one or more driving currents including the first driving current.

3. The voltage regulator of claim 2, wherein:
the first driving current source is a variable current source configured to operate in response to the control from the recovery enhancement circuit.

4. The voltage regulator of claim 3, wherein the recovery enhancement circuit comprises:
a difference detection circuit configured to generate a supplement current control voltage based on a difference voltage between the output voltage and the pass gate voltage; and
a driving current control circuit configured to control a value of the first driving current based on the supplement current control voltage.

5. The voltage regulator of claim 4, wherein the driving current control circuit is configured to:
generate a supplement driving current based on the supplement current control voltage; and
provide the supplement driving current to the first driving current source.

6. The voltage regulator of claim 5, the first driving current source comprises:
a driving constant current source configured to generate a driving constant current; and
a driving variable current source that is connected in parallel with the driving constant current source and is configured to mirror the supplement driving current.

7. The voltage regulator of claim 4, wherein the difference detection circuit comprises a comparison amplifier,
wherein the comparison amplifier includes,
a third input terminal configured to receive the output voltage;
a fourth input terminal configured to receive a voltage that is higher than the pass gate voltage by an offset voltage; and
a second output terminal configured to output the supplement current control voltage.

8. The voltage regulator of claim 2,
wherein the differential input circuit comprises:
a first differential input transistor connected between a first node and a second node, wherein the first differential input transistor includes a first gate terminal configured to receive the reference voltage;
a second differential input transistor connected between the first node and a third node, wherein the second differential input transistor includes a second gate terminal configured to receive the feedback voltage; and
the first driving current source configured to provide the first driving current to the first node.

9. The voltage regulator of claim 8, wherein the amplification circuit comprises:
a first amplification transistor connected between the second node and a ground node, wherein the first amplification transistor includes a third gate terminal connected to the second node; and
a second amplification transistor connected between the third node and the ground node, wherein the second amplification transistor includes a fourth gate terminal connected to the second node,
wherein the third node is connected to the output node.

10. The voltage regulator of claim 8, wherein the amplification circuit comprises:
a third amplification transistor connected between the second node and a ground node, wherein the third amplification transistor includes a fifth gate terminal connected to a fourth node;
a fourth amplification transistor connected between the third node and the ground node, wherein the fourth amplification transistor includes a sixth gate terminal connected to the fourth node;
a fifth amplification transistor connected between the second node and the fourth node;
a sixth amplification transistor connected between the third node and a fifth node;
a seventh amplification transistor connected between the fourth node and a sixth node;
an eighth amplification transistor connected between the fifth node and a seventh node;
a second driving current source configured to provide a second driving current to the sixth node, the one or more driving currents including the second driving current; and
a third driving current source configured to provide a third driving current to the seventh node, the one or more driving currents including the third driving current,
wherein gate terminals of the fifth amplification transistor and the sixth amplification transistor are connected to each other, gate terminals of the seventh amplification transistor and the eighth amplification transistor are connected to each other, and the fifth node is connected to the output node.

11. A method of operating a voltage regulator, the method comprising:
setting a driving current of an error amplifier to a first current, the voltage regulator including the error amplifier, and the error amplifier being configured to generate a pass gate voltage;
increasing the driving current to a second current higher than the first current, in response to a difference voltage for an output voltage of the voltage regulator and the pass gate voltage being greater than a first supplement threshold voltage; and
decreasing the driving current to the first current in response to the difference voltage being less than a second supplement threshold voltage.

12. The method of claim 11, wherein:
the difference voltage corresponds to a value obtained by subtracting a voltage level of the pass gate voltage from a voltage level of the output voltage.

13. The method of claim 11, wherein the voltage regulator further comprises a pass transistor that is connected between an input node that is configured to receive an input voltage and an output node that is configured to provide the output voltage,
wherein the pass transistor is configured to operate in response to the pass gate voltage, and
wherein the error amplifier is configured to generate the pass gate voltage based on a feedback voltage generated based on the output voltage.

14. The method of claim 11, wherein the increasing the driving current is performed in response to a decrease of a load connected to the voltage regulator.

15. The method of claim 11, wherein the decreasing the driving current is performed in response to an increase of a load connected to the voltage regulator.

16. A voltage regulator, comprising:
an error amplifier configured to generate a pass gate voltage;
a pass transistor connected to an output node and configured to operate in response to the pass gate voltage; and
a recovery enhancement circuit configured to increase one or more driving currents of the error amplifier, in response to an overshoot occurring in a voltage level of the output node.

17. The voltage regulator of claim 16, wherein the recovery enhancement circuit comprises:
a difference detection circuit configured to determine an occurrence of the overshoot based on a difference between an output voltage of the output node and the pass gate voltage; and
a driving current control circuit configured to control the one or more driving currents based on the occurrence of the overshoot determined by the difference detection circuit.

18. The voltage regulator of claim 17, wherein the difference detection circuit includes a comparison amplifier,
wherein the comparison amplifier includes,
a first input terminal configured to receive the output voltage;
a second input terminal configured to receive a voltage higher than the pass gate voltage by an offset voltage; and
a first output terminal configured to output a supplement current control voltage, the supplement current control voltage configured to control the driving current control circuit.

19. The voltage regulator of claim 16, further comprising a first resistor connected between the output node and a feedback node, and a second resistor connected between the feedback node and a ground voltage, wherein:
the error amplifier includes a third input terminal configured to receive a reference voltage, a fourth input terminal connected to the feedback node, and a second output terminal configured to output the pass gate voltage; and
the pass transistor is connected between an input voltage and the output node.

20. The voltage regulator of claim 19, wherein the error amplifier comprises:
a differential input circuit configured to receive the reference voltage and a feedback voltage corresponding to the feedback node; and
an amplification circuit configured to generate the pass gate voltage in response to a control from the differential input circuit,
wherein at least one of the differential input circuit and the amplification circuit comprises a driving current source configured to generate one of the one or more driving currents in response to the control from the recovery enhancement circuit.
